(19) United States
(12) Patent Application Publication
(10) Pub. No.: US 2005/0145892 A1
(43) Pub. Date: Jul. 7, 2005

(54) Mask, semiconductor device manufacturing method, and semiconductor device

(75) Inventors: Shinichiro Nohdo, Kanagawa (JP); Shigeru Moriya, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 10/506,147

(22) PCT Filed: Mar. 13, 2003
(86) PCT No.: PCT/JP03/02966

(30) Foreign Application Priority Data
Mar. 13, 2002 (JP) 2002-068745

(51) Int. Cl. H01L 29/76; H01L 31/113; G03C 5/00

(52) U.S. Cl. 257/288; 438/706; 430/296

(57) ABSTRACT

A mask capable of improving superimposing accuracy of patterns drawn on a plurality of masks, a production method of a semiconductor device capable of improving a yield of semiconductor devices, and a semiconductor device wherein a pattern can be made finer are provided. A mask including a plurality of mask regions formed with mutually different mask patterns to be transferred to the same device, wherein all the mask patterns are drawn by the same electron beam exposure means; the mask pattern of each mask is drawn with being divided to a plurality of deflection regions; the deflection region is in a range wherein a part of the mask pattern can be drawn on the mask by deflecting an electron beam by fixing the electron beam exposure means; and the deflection region is divided, so that the mask pattern in any deflection region of each of the masks is transferred on the same region on the device as a mask pattern in one deflection region of other mask, a production method of a semiconductor device using the mask and a semiconductor device produced using the mask.

### TECHNICAL FIELD

The present invention relates to a mask used for lithography, etc., a production method of a semiconductor device and a semiconductor device.

### BACKGOUND ART

When producing a semiconductor integrated circuit device, generally, a plurality of masks are used for exposing a pattern of respective device elements (for example, a trench layer, gate layer, contact layer and wiring layer, etc.) on a wafer. This exposure technique is called lithography, and a variety of lithography has been developed, such as photolithography, X-ray lithography, LEEPL (low energy electron-beam proximity projection lithography; refer to J. Vac. Sci. Technol. B. 17(6), 1999), EB (electron beam) stepper, and ion beam lithography. In any lithography, an exposure mask is produced by using an electron beam exposure technique.

An electron beam exposure apparatus used for drawing a mask pattern has a deflection region (a region wherein an electron beam can be deflected at necessary accuracy by a deflector) of several millimeters or so at maximum. Accordingly, exposure for drawing a mask pattern on a mask is performed by dividing the mask to a plurality of deflection regions and driving a stage between the deflection regions.

However, in the deflection regions, displacement of a beam called deflection distortion arises due to an effect of aberration of a deflector. In the case of forming mask patterns on a plurality of masks for a device, when a way of dividing to deflection regions is different between masks, accuracy of aligning patterns formed on the respective masks on a wafer declines.

An example will be explained with reference to FIGS. 1A and 1B. A mask A in FIG. 1A and a mask B in FIG. 1B indicate masks for the same device, and the mask A and the mask B are formed with patterns of different device elements. A pattern of the mask A and a pattern of the mask B are superimposed on the device. The patterns of the mask A and the mask B are drawn by using the same electron beam exposure apparatus.

The mask A is divided to deflection regions 1a by the number of 4 by 4 in FIG. 1A, and the mask B is divided to deflection region 1b by the number of 5 by 6 in FIG. 1B. When there is no deflection distortion in the electron beam exposure apparatus for mask pattern drawing, each of the deflection regions 1a and 1b in FIG. 1A and FIG. 1B become rectangular or square, but each of the deflection regions 1a and 1b actually becomes a distorted shape as shown in FIG. 1A and FIG. 1B due to deflection distortion. Along therewith, a pattern in the deflection regions 1a and 1b is also distorted.

Since the distortion of a deflection region reflects characteristics of the deflector of the electron beam exposure apparatus, a common tendency is observed in the mask A and mask B in the distortion direction of the deflection regions. However, since sizes of the divided deflection regions are different in the mask A and the mask B, displacement of the pattern at one point on the mask A and displacement of the pattern at the same point on the mask B (a point to be superimposed fundamentally on the device) are not matched.

Accordingly, the displacement of the pattern varies not only in each mask but between the masks. When transferring a pattern of respective device elements on a wafer by using such masks A and B, accuracy of superimposing between the device elements cannot be secured sufficiently.

Another example will be explained with reference to FIGS. 2A and 2B. For example, in lithography using a low energy electron beam of 2 keV or so, an electron beam does not transmit a thin film (membrane) material of a mask, so that a mask formed with holes in a predetermined pattern (a stencil mask) is used as the membrane.

In a stencil mask, a center portion of a donut shaped pattern is not supported in some cases, partial stress intensity arises on the membrane when forming a specific pattern, or mechanical strength of the mask is declined in other cases. Thus, a desired pattern is divided complementarily to form complementary masks.

FIG. 2A and FIG. 2B show a pair of complementary masks A and B, wherein the complementary mask A and the complementary mask B are formed with mutually different complementarily divided patterns. Complementarily divided patterns formed on the stencil masks are for complementarily dividing a pattern of a device element and combined on the device. The patterns of the complementary mask A and the complementary mask B are drawn by using the same electron beam exposure apparatus.

In FIG. 2A and FIG. 2B, a size of one of deflection regions 2a and 2b is same, but the dividing positions are different. In the same way as in FIG. 1A and FIG. 1B, the respective deflection regions 2a and 2b become distorted shape due to deflection distortion. Along therewith, patterns in the deflection regions 2a and 2b are also distorted.

Displacement of a pattern at a certain point on the complementary mask A and displacement of a pattern at the same point on the complementary mask B are not matched. Since displacement of the pattern varies in each complementary mask and between the complementary masks, accuracy of combining the complementarily divided patterns cannot be secured sufficiently even if multiple exposures are performed. Furthermore, when transferring a pattern of respective device elements by complementary dividing as above, superimposing accuracy between the device elements are also remarkably declined.

The case where accuracy of combining patterns between device elements declines as shown in FIGS. 1A and 1B and the case where accuracy of combining patterns in a device element and between device elements decline as shown in FIGS. 2A and 2B cause connection failure and short-circuiting, etc. and a yield of the semiconductor device decline. When accuracy of aligning the patterns is poor, the patterns are hard to be made finer and the semiconductor device cannot be highly integrated.

### DISCLOSURE OF THE INVENTION

The present invention was made in consideration of the above problems and has as an object thereof to provide a mask capable of heightening accuracy of superimposing mask patterns drawn on different regions of a plurality of masks or the same mask.

Also, an object of the present invention is to provide a production method of a semiconductor device capable of improving a yield of the semiconductor device by heightening accuracy of aligning patterns in a device.

Furthermore, an object of the present invention is to provide a highly integrated semiconductor device with high accuracy of aligning patterns between device elements and in a device element.

To attain the above objects, a mask of the present invention is characterized by including a plurality of lithography mask regions formed with mutually different mask patterns to be transferred to the same device, wherein the mask patterns of all of the mask regions are drawn by the same charged particle beam exposure means; the mask pattern of each of the mask regions is drawn with being divided to a plurality of deflection regions; the deflection region is in a range wherein a part of the mask pattern can be drawn on the mask region by deflecting a charged particle beam irradiated on the mask region without changing relative positions of the charged particle beam exposure means and the mask region; and the deflection region is divided, so that the mask pattern in any deflection region of each of the mask regions is transferred on the same region on the device as the mask pattern in each one of deflection region of other mask region.

As a result, deflection distortion depending on a deflector of the charged particle beam exposure means can be matched between mask regions, and accuracy of aligning patterns between mask regions can be heightened. Preferably, the charged particle beam is an electron beam. According to the electron beam exposure means, a fine mask pattern can be easily drawn.

Preferably, a distribution of positional disposition of the mask patterns in the deflection regions approximately matches with distributions of positional disposition of the mask patterns in other deflection regions in the mask region and deflection regions of other mask region. When drawing mask patterns by the same charged particle beam exposure means, a common tendency is observed in positional displacement of mask patterns in deflection regions. According to the present invention, deflection distortion can be matched between mask regions, so that accuracy of aligning patterns between mask regions is improved.

Preferably, the mask patterns of the respective mask regions are patterns of different device elements. For example, when one mask region is drawn a mask pattern of a gate layer as one of device elements, and other mask region is drawn a pattern of a contact layer as other device element, deflection distortion is matched between the mask regions, so that accuracy of aligning patterns of the gate layer and the contact layer becomes high. As other example of device elements, a trench layer and wiring layer, etc. may be mentioned, and device elements formed on the mask regions are not limited.

Alternately, preferably, the mask patterns of the respective mask regions are complementarily divided patterns for forming the same device element. For example, in the case where a pattern of a gate layer as one device element is divided and drawn on a plurality of mask regions, deflection distortion matches between the mask regions. Accordingly, accuracy of aligning the complementarily divided patterns is improved.

Preferably, the mask is a stencil mask. For example, the present invention can be applied to a mask used in electron beam transfer type lithography, such as LEEPL.

Preferably, a plurality of the mask regions is formed on the same mask. When a plurality of mask regions are formed on the same mask, patterns formed on the mask regions may be either of patterns of different device elements and complementarily divided patterns for forming the same device element.

Masks for forming different device elements are different only in the patterns and a mask producing process is in common. Accordingly, when patterns of different device elements are arranged on different mask regions on the same mask, mask materials can be reduced, works on mask production can be reduced, and the costs can be reduced comparing with those in the case of producing a mask for each device element.

On the other hand, when arranging complementarily divided patterns for forming the same device element on a plurality of mask regions on the same mask, exchange of masks becomes unnecessary and multiple exposures becomes possible only by changing relative positions of the mask and an exposure object (a wafer, etc.) in multiple exposures of complementarily divided patterns. Accordingly, mass production of semiconductor devices can be made high at speed. Also, comparing with the case of producing a plurality of complementary masks, mask materials can be reduced, works on mask production can be reduced, and the costs can be reduced.

To attain the above objects, a production method of a semiconductor device of the present invention is characterized by including a plurality of lithography steps for transferring to a device mask patterns of a mask having a plurality of mask regions on which the mutually different mask patterns are drawn by the same charged particle beam exposure means, wherein the mask pattern of the mask regions is drawn with being divided to a plurality of deflection regions; the deflection region is in a range wherein a part of the mask pattern can be drawn on the mask region by deflecting a charged particle beam irradiated on the mask region without changing relative positions of the charged particle beam exposure means and the mask region; and the deflection region is divided, so that the mask pattern in any deflection region of the mask regions is transferred on the same region on the device as the mask pattern in each one of deflection region of other mask region.

As a result, accuracy of aligning patterns in the device can be made high and a yield of the semiconductor device can be improved. Also, accuracy of fine processing of device elements, such as a gate layer, and mass production of the semiconductor device can be realized.

Also, to attain the above objects, a semiconductor device of the present invention characterized in that mask patterns formed on a mask are transferred thereon by a plurality of lithography steps, wherein the mask has a plurality of mask regions on which mutually different mask patterns are drawn by the same charged particle beam exposure means; the mask pattern of each of the mask regions is drawn with being divided to a plurality of deflection regions; the deflection region is in a range wherein a part of the mask pattern can be drawn on the mask region by deflecting a charged particle beam irradiated on the mask region without changing relative positions of the charged particle beam exposure means and the mask region; and the deflection region is divided, so that the mask pattern in any deflection region of the mask regions is transferred on the same region on the device as the mask pattern in each one of deflection region of other mask region.

As a result, accuracy of aligning patterns in a device can be made high and the semiconductor device can be made finer and more highly integrated.

### BRIEF DESCRIPTION OF DRAWINGS

FIG. 1A and FIG. 1B are plan views of a conventional mask and show arrangements of deflection regions when drawing a mask pattern.

FIG. 2A and FIG. 2B are plan views of a conventional complementary mask and show arrangements of deflection regions when drawing a mask pattern;

FIG. 3A is a plan view showing a mask region, and FIG. 3B is a plan view showing an ideal state of dividing the mask region to deflection regions.

FIG. 4A and FIG. 4B are plan views of a mask according to an embodiment 1 of the present invention and show arrangements of deflection regions when drawing a mask pattern.

FIG. 5A and FIG. 5B are plan views of a complementary mask according to an embodiment 2 of the present invention and show arrangements of deflection regions when drawing a mask pattern.

FIG. 6A is a plan view of a stencil mask according to an embodiment 3 of the present invention, FIG. 6B is a sectional view of the mask in FIG. 6A, and FIG. 6C is a perspective view showing a part of the mask in FIG. 6A.

FIG. 7 is a plan view showing a mask region of the mask in FIG. 6A.

FIG. 8 is a schematic view showing an example of an exposure apparatus using the mask in FIG. 6A.

FIG. 9 is a plan view showing an example of a semiconductor device of the present invention.

FIG. 10A to FIG. 10C are views for explaining a production method of the semiconductor device in FIG. 9.

FIG. 11 is a flowchart showing a production method of a semiconductor device of the present invention.

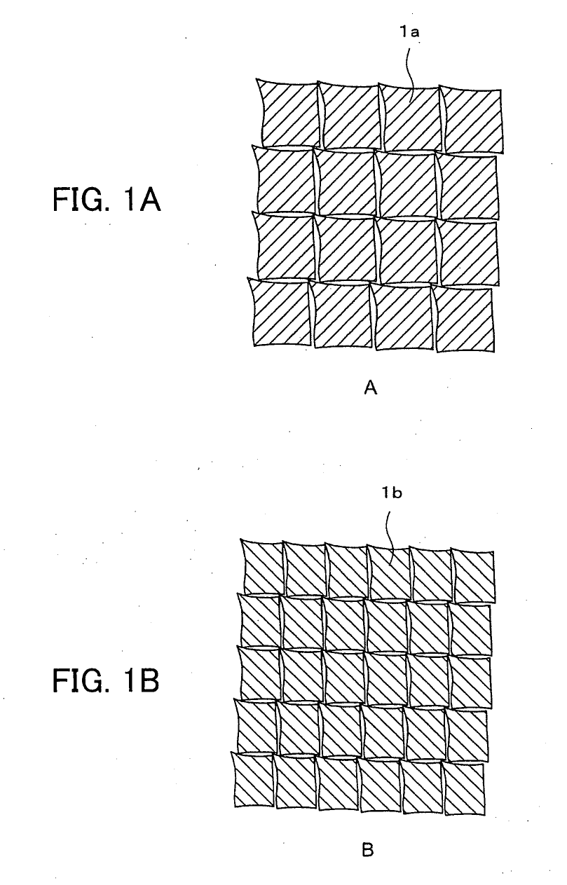

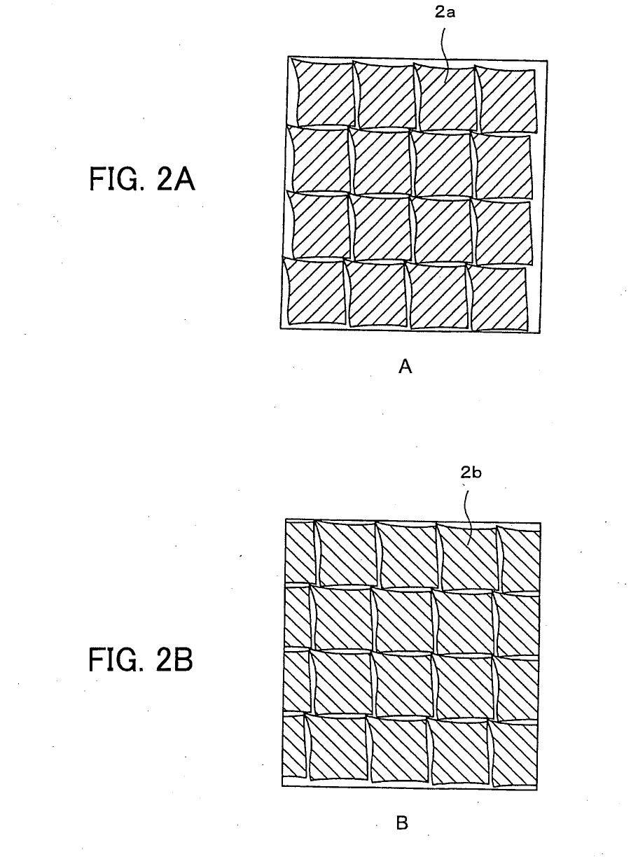

### BEST MODE FOR CARRYING OUT THE INVENTION

Below, preferred embodiments of a mask, a production method of a semiconductor device and a semiconductor device of the present invention will be explained with reference to the drawings.

### EMBODIMENT 1

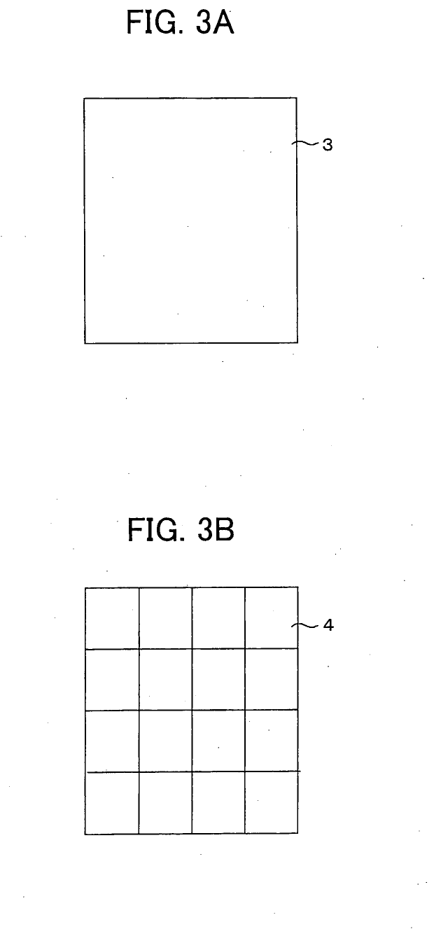

FIG. 3A is a plan view showing a mask region 3 used in lithography, and FIG. 3B is a plan view showing a state where the mask region 3 in FIG. 3A is divided to a plurality of deflection regions 4. The mask region 3 is formed with a pattern of a device element (for example, trench layer, a gate layer, a contact layer and a wiring layer, etc.).

In lithography, a mask pattern is transferred on a wafer by an exposure beam transmitting selectively a part of the mask region 3. The exposure beam irradiated on the mask region 3 may be any of an ultraviolet ray, an X-ray, an electron beam and an ion beam, etc. and is not limited.

Also, the mask region 3 may have either of the configuration wherein a film for blocking the exposure beam is formed on a part of the base material for letting the exposure beam pass through and the configuration wherein through holes are provided on the base material for shielding the exposure beam. As an example of the former, a photomask used in photolithography, and for example, a membrane mask used in lithography using a high energy electron beam of 10 keV or more may be mentioned. As an example of the latter, a stencil mask used in LEEPL explained above and EB stepper, etc. may be mentioned.

In any case, the mask pattern is normally formed by drawing a pattern with an electron beam on a resist applied on the mask region 3 and performing processing on a part of the mask region 3 by using the resist as a mask. In the electron beam exposure apparatus, a mask pattern is drawn by deflecting an electron beam by a deflector. A deflection region 4 is a region wherein an electron beams can be deflected with required accuracy by a deflector and is a several millimeters or so at maximum. Normally, the mask region 3 is obviously larger than the deflection region 4, the mask region 3 is divided to a plurality of deflection regions 4, and a mask pattern is drawn for each deflection region 4.

Note that the mask of embodiments of the present invention has a plurality of mask regions; the mask regions may be formed separately on a plurality of masks or formed on different regions on one mask. In the present embodiment, an example of creating two masks each having one mask region will be explained.

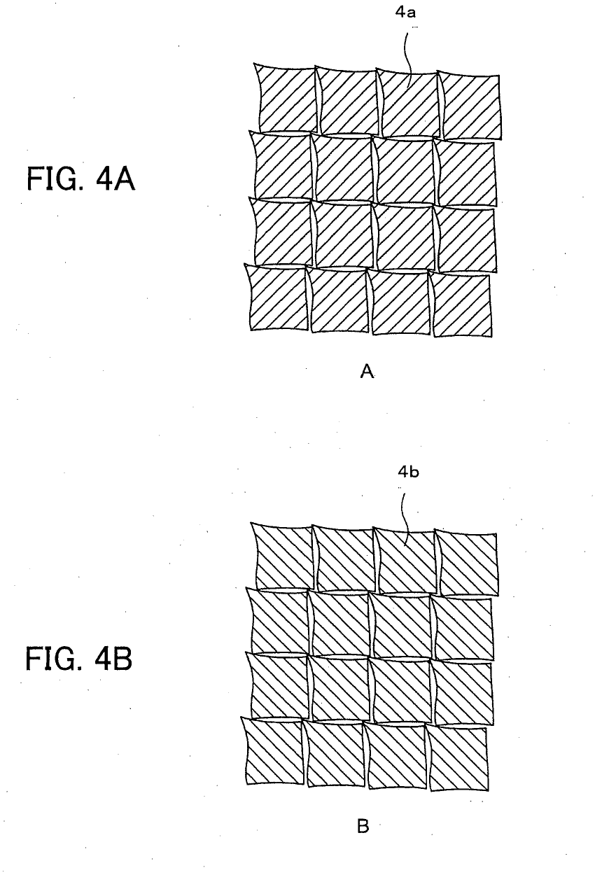

FIG. 4A and FIG. 4B show a mask region of the same device, wherein the mask region A and the mask region B are formed with patterns of different device elements. A pattern of the mask region A and a pattern of the mask region B are superimposed on the device. Patterns of the mask region A and the mask region B are drawn by using the same electron beam exposure apparatus.

Here, for a simple explanation, an example of providing the mask region A on one of the two masks for the same device and providing the mask region B on the other was shown, but the present invention may be applied to the case of providing one mask region to each of three or more masks. According to the present invention, alignment accuracy of patterns between masks can be improved, so that the larger the number of masks to be applied with the present invention, the larger the effect of improving the alignment accuracy between device elements.

In FIG. 4A, the mask region A is divided to deflection regions 4a by the number of 4 by 4, and in FIG. 4B, the mask region B is divided to deflection regions 4B of by the number 4 by 4 at the same position. If there is no deflection distortion in the electron beam exposure apparatus for drawing a mask pattern, each of the deflection regions 4a and 4b in FIG. 4A and FIG. 4B become rectangular or square as shown in FIG. 3B. However, each of the deflection regions 4a and 4b actually becomes a distorted shape as shown in FIG. 4A and FIG. 4B due to deflection distortion. Along therewith, patterns in the deflection regions 4a and 4b are also distorted.

Since distortion of a deflection region reflects characteristics of the deflector of the electron beam exposure apparatus, a common tendency is observed in the distortion direction and pattern displacement of the deflection regions in the mask region A and mask region B. Since the way of dividing to the deflection regions is the same in the mask region A and the mask region B, displacement of the pattern at one point on the mask region A and displacement of the pattern at the same point on the mask region B (a point to be superimposed fundamentally on the device) are easily matched.

In each deflection region, there is a distribution of a part with large displacement of the pattern and a part with small displacement of the pattern, but the distortion tendency matches between the mask region A and the mask region B. When transferring a pattern of device elements on a wafer by using the mask regions A and B as above, accuracy of aligning the patterns between device elements can be improved.

According to a production method of a semiconductor device of the present embodiment, one pattern of device elements (for example, a trench layer, a gate layer, a contact layer and a wiring layer, etc.) is transferred by lithography using the mask region A and a pattern of other device element is transferred by lithography using the mask region B. As a result, alignment accuracy of patterns between layers becomes high and, for example, connection failure and short-circuiting, etc. are reduced. Accordingly, a yield of the semiconductor device can be improved.

### EMBODIMENT 2

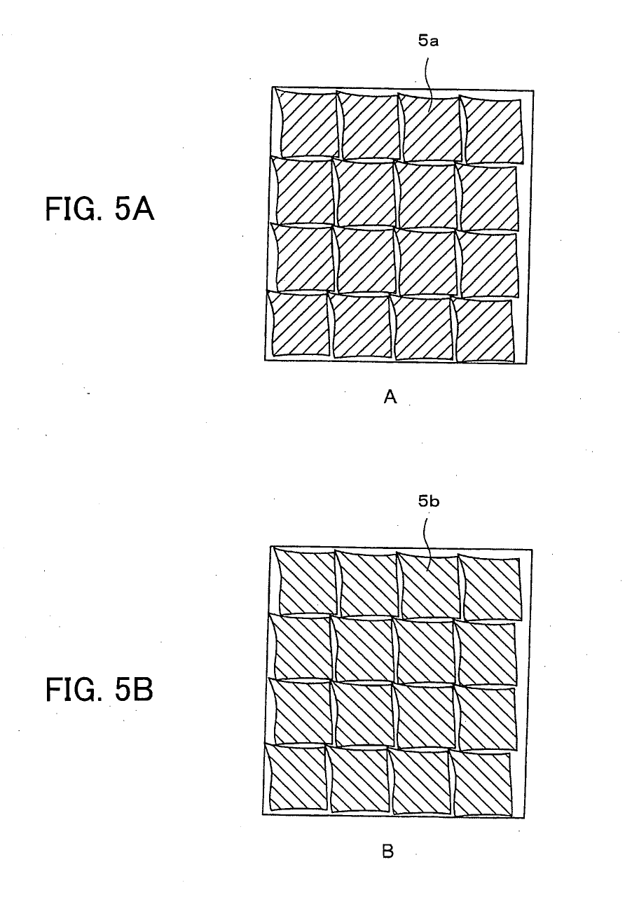

FIG. 5A and FIG. 5B show the mask region A provided on one of a pair of complementary masks and a mask region B provided on the other one. Below, they will be referred to as complementary mask regions A and B. The complementary mask region A and the complementary mask region B are formed with mutually different complementarily divided patterns. The complementarily divided pattern formed on a stencil mask is obtained by complementarily dividing a pattern of a device element and is combined on the device. Patterns of the complementary mask region A and the complementary mask region B are drawn by using the same electron beam exposure apparatus.

The pair of complementary masks provided with the complementary mask regions A and B are, for example, stencil masks for a low energy electron beam transfer type lithography. Alternately, they may be stencil masks for high energy electron beam transfer type lithography, ion beam lithography or other charged particle beam lithography.

In the case of a stencil mask, a complementary mask becomes necessary for transferring a specific pattern, for example a donut shaped pattern, etc. When forming a donut shaped pattern with a stencil mask, the center part surrounded by the pattern is not supported. Also, for example, a pattern being long in one direction is distorted due to an internal stress, etc. of a membrane and positional accuracy of the pattern declines.

Patterns causing the above problems are divided and formed as a plurality of mask regions (complementary masks). By performing multiple exposures by using the complementary masks, a pattern is transferred complementarily (complementary division). Here, the complementary mask indicates a mask formed by assigning patterns obtained by dividing a pattern in a certain section on the device. When the complementary masks are superimposed, a pattern in the section before dividing is restored.

The complementary mask region A is divided to deflection regions 5a by the number of 4 by 4 in FIG. 5A, and the complementary mask region B is divided to deflection regions 5b by the number of 4 by 4 at the same position in FIG. 5B. Since the way of dividing into deflection regions is the same in the complementary mask regions A and B, displacement of a pattern at one point on the complementary mask region A and displacement of a pattern at the same point on the complementary mask region B are easily matched. A tendency and distribution of distortion are approximately matched between these masks. Accordingly, when a pattern of a device element on the wafer is transferred by using the two complementary masks formed with the complementary mask regions A and B, combining accuracy between the complementarily divided patterns can be improved.

According to a production method of a semiconductor device of the present embodiment, first, exposure is performed by using one complementary mask provided with the complementary mask region A to transfer one complementarily divided pattern. Next, exposure is performed by using the other complementary mask provided with the complementary mask region B to transfer the other complementarily divided pattern. As a result, combining accuracy of the complementarily divided patterns becomes high and, for example, connection failure and short-circuiting, etc. are reduced. Accordingly, a yield of semiconductor devices can be improved.

### EMBODIMENT 3

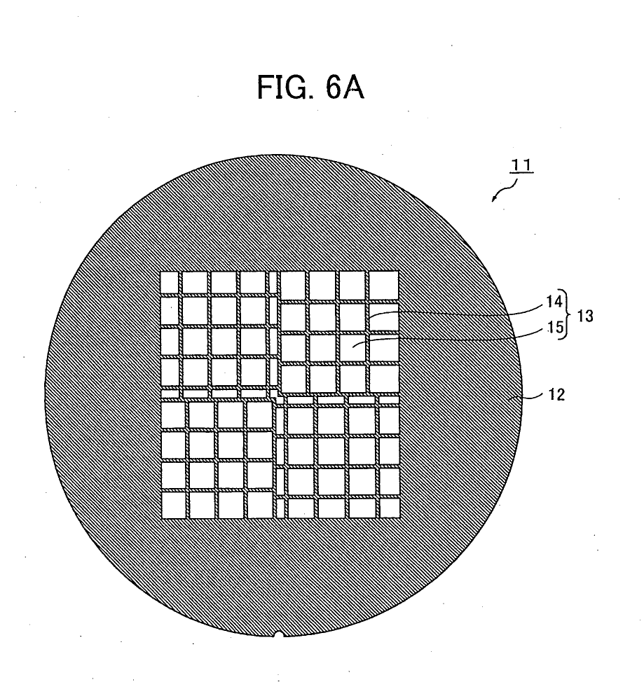

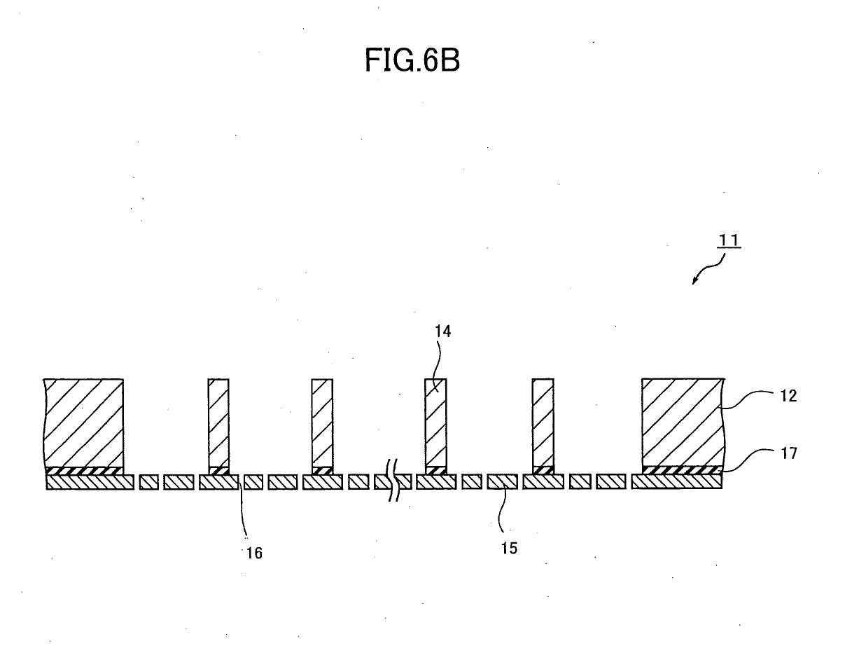

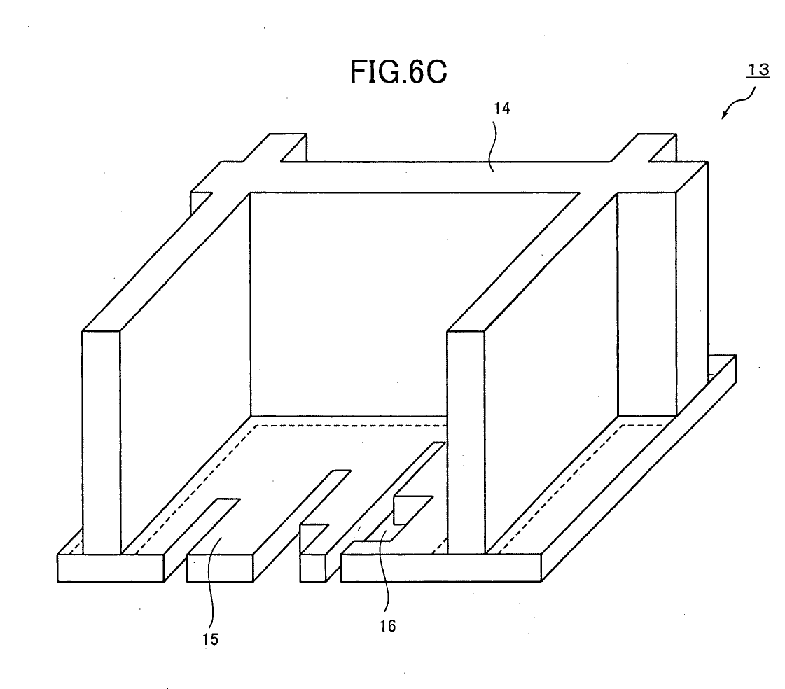

In the present embodiment, an example wherein a plurality of mask regions is provided in the same mask will be explained. FIG. 6A is a plan view of a stencil mask 11 used in the present embodiment and the stencil mask 11 is preferably used in LEEPL. FIG. 6B is a sectional view of the stencil mask 11 in FIG. 6A, and FIG. 6C is a perspective view showing a part of the stencil mask 11 in FIG. 6A.

As shown in FIG. 6A to FIG. 6C, the stencil mask 11 comprises a supporting frame 12 and a membrane 13 surrounded thereby. A part of the membrane 13 is formed with a beam shaped reinforcing member (hereinafter, referred to as a beam 14) for supporting the membrane 13. A part of the membrane 13 surrounded by the beams 14 (hereinafter, referred to as a pattern formation region 15) is formed an opening portion 16 in a predetermined pattern. Normally, the opening portion 16 is formed to be an inner side of dotted lines in the pattern formation region 15 shown in FIG. 6C to be kept away from the beams 14.

Note that other than the opening portion 16, a mask side alignment mark is also formed on a part of the pattern formation region 15. When performing exposure on a wafer by using the stencil mask 11, a position of a wafer side alignment mark provided on the wafer and a position of the mask side alignment mark provided on the stencil mask 11 are detected for aligning the stencil mask 11 with the wafer.

The supporting frame 12 and the beams 14 of the stencil mask 11 are, for example, portions left after removing a part of a silicon wafer by etching. A portion where the silicon wafer is removed becomes a pattern formation region 15. It is not necessary to provide an auxiliary layer 17 shown in FIG. 6B, but the auxiliary layer 17 is used as an etching stopper layer in a step of forming the supporting frame 12 and the beams 14 by performing etching, for example, on the silicon wafer and a step of forming the opening portion 16 by performing etching on the membrane 13 of the pattern formation region 15. As the auxiliary layer 17, a layer having other functions may be formed.

The configuration of the above stencil mask 11 is not limited to the configuration shown in FIG. 6A to FIG. 6C and may be, for example, the configuration wherein the membrane 13 has a plurality of layers. Also, an arrangement of the beams 14 is not limited to the example shown in FIG. 6A to FIG. 6C and the beams may be, for example, arranged in stripe.

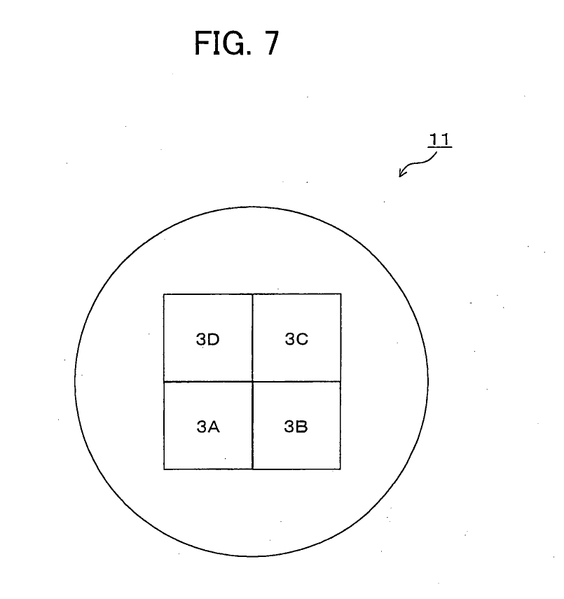

FIG. 7 is a plan view showing mask regions 3A to 3D provided on the stencil mask 11 in FIG. 6A to FIG. 6C. The mask regions 3A to 3D are formed with complementarily divided patterns, and by exposing the patterns formed on the mask regions 3A to 3D superimposed on the same region of an exposure object, a desired pattern is complementarily transferred on the exposure object.

The patterns cannot be arranged on portions formed with the beams in FIG. 6A to FIG. 6C, but the beams on the respective mask regions are formed in mutually different phases as shown in FIG. 6A. Specifically, the beams 14 on four mask regions 3A to 3D are arranged, so that a part arranged with the beams 14 on one mask region becomes a pattern formation region 15 on other at least two mask regions.

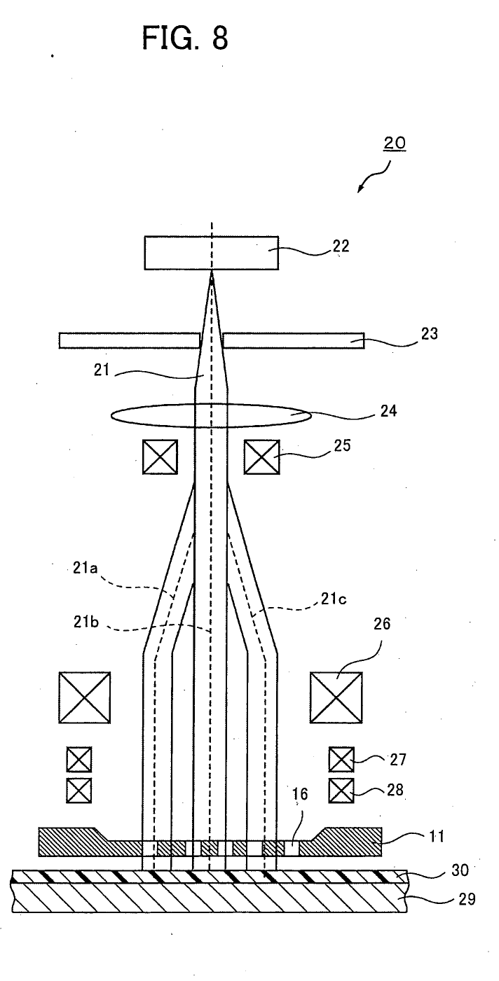

FIG. 8 is a schematic view showing an example of an electron beam exposure apparatus used in LEEPL. The exposure apparatus 20 in FIG. 8 comprises an aperture 23, a condenser lens 24, a pair of main deflectors 25 and 26 and a pair of fine adjustment deflectors 27 and 28 other than an electron gun 22 for generating an electron beam 21.

The aperture 23 constrains the electron beam 21. The condenser lens 24 makes the electron beam 21 a parallel beam. The main deflectors 25 and 26 and the fine adjustment deflectors 27 and 28 are deflection coils. The main deflectors 25 and 26 deflect the electron beam 21 to make it emit basically in the direction perpendicular to the surface of the stencil mask 11.

Electron beams 21a to 21c in FIG. 8 are to show a state that the electron beam 21 scanning on the stencil mask 11 irradiates in the direction perpendicular to respective positions on the stencil mask 11, and not to show the electron beams 21a to 21c irradiating the stencil mask 11 at one time.

The fine adjustment deflectors 27 and 28 deflect the electron beam 21 to make it irradiate in the direction perpendicular to the surface of the stencil mask 11 or irradiate slightly inclined direction from the perpendicular. An incident angle of the electron beam 21 is optimized in accordance with a position, etc. of the opening portion 16 formed in a predetermined pattern on the stencil mask 11. The incident angle of the electron beam 21 is 7 to 10 mrad or so at maximum.

Energy of the electron beam for scanning the stencil mask 11 is several keV to tens of keV, for example, 2 keV. A pattern of the stencil mask 11 is transferred to a resist 30 on the wafer 29 by an electron beam transmitted through the opening portion 16. The stencil mask 11 is arranged immediately above the wafer 29 by leaving a space of several tens of μm or so between the stencil mask 11 and the wafer 29.

In the exposure apparatus as above, after making the stencil mask 11 face to the resist 30 on the wafer 29 and exposing patterns of the mask regions 3A to 3D (refer to FIG. 7), the wafer 29 is shifted by an amount of one mask region with respect to the stencil mask 11. Consequently, a portion immediately after being exposed by one mask region faces other mask region. By repeating the exposure and shift of the wafer 29 as such, the four mask regions 3A to 3D can be exposed on the same part.

When forming the opening portion 16 shown in FIG. 6B on the pattern formation region 15 in production of the stencil mask 11 used for the above exposure, a predetermined pattern is drawn by an electron beam on the resist applied on the pattern formation region 15. By using as a mask the resist pattern obtained by developing the resist, dry etching is performed on the pattern formation region 15. The electron beam drawing is performed by dividing each of the mask regions 3A to 3D to a plurality of deflection regions. At this time, the mask regions 3A to 3D are divided to the same number of deflection regions at the same position (a position to be superimposed on the device).

In the deflection region, aberration of the deflector leads to positional distortion of the beam called deflection distortion. When the mask regions 3A to 3D are divided to a plurality of deflection regions in the same dividing way, deflection distortion at the same position (a position to be superimposed on the device) on the mask regions 3A to 3D are matched. Complementarily divided patterns formed on the mask regions 3A to 3D are combined on the device by exposure with the four mask regions 3A to 3D, but deflection distortion is in common between the mask regions 3A to 3D, so that combining accuracy of the complementarily divided patterns can be improved.

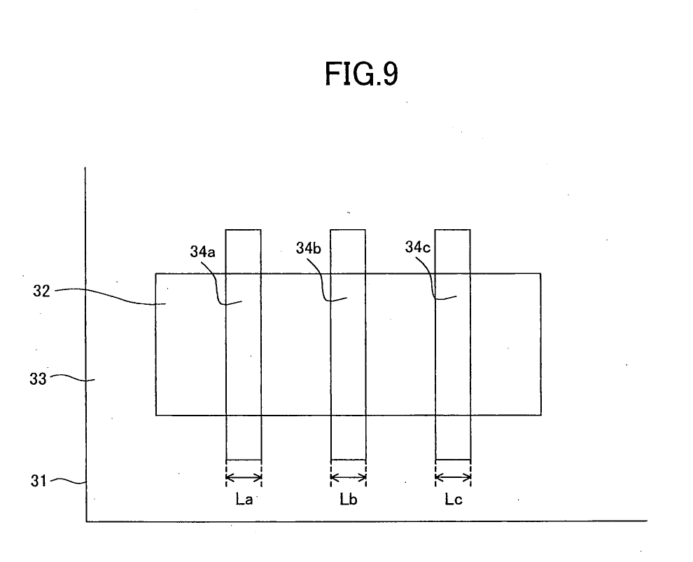

FIG. 9 is an example of a plan view showing a part of a semiconductor device produced by a step including exposure of a pattern by LEEPL as above. FIG. 9 is an example of a MOS transistor, wherein an active region 32 is formed in a chip 31 and an element separation region 33 is formed around the active region 32. The active region 32 has a predetermined conductivity, and the element separation region 33 electrically insulates between the active region 32 and an adjacent active region (not shown). Gate electrodes 34a to 34c made by polycrystalline silicon or silicide, etc. are formed to have gate lengths of La to Lc, respectively, on the active region 32.

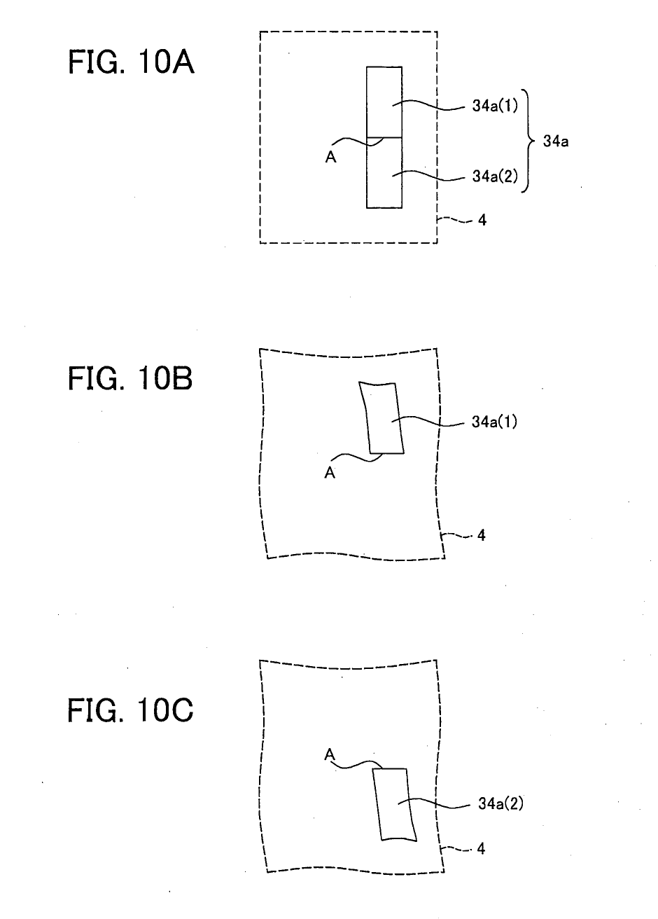

The gate electrodes 34a to 34c are formed with patterns as one device element. Specifically, a pattern of a gate layer including the gate electrodes 34a to 34c is complementarily divided, and complementarily divided patterns are formed on the mask regions 3A to 3D in FIG. 7. For example, as shown in FIG. 10A, the gate electrode 34a is complementarily divided at a position of a straight line A.

In this case, one complementarily divided pattern 34a (1) is formed on one mask region and the other pattern 34a (2) is formed on other one mask region. Note that a same pattern may be repeatedly formed on two or more mask regions. Here, a dotted line in FIG. 10A is considered to be one deflection region 4. Since the four mask regions 3A to 3D (refer to FIG. 7) are divided to a plurality of deflection region in the same dividing way, the deflection region 4 in FIG. 10A matches on the mask region formed with the pattern 34a (1) and the mask region formed with the pattern 34a (2).

FIG. 10B shows the pattern 34a (1) drawn on one mask region, and FIG. 10C shows the pattern 34a (2) drawn on another mask region. As is shown with emphasis in FIG. 10B and FIG. 10C, different mask regions have common deflection distortion. Accordingly, at a position of the straight line A for complementarily dividing the gate electrode pattern 34a (refer to FIG. 10A), displacement of the pattern 34a (1) and that of the pattern 34a (2) are matched. Consequently, breaking of the gate electrode 34a (refer to FIG. 9) formed on the device is prevented.

While not illustrated, when a way of dividing to deflection regions is different between the mask region formed with the pattern 34a (1) and the mask region formed with the pattern 34a (2), displacement of the pattern 34a (1) and that of the pattern 34a (2) become different in some cases at the position of the straight line A for complementarily dividing the pattern 34a in FIG. 10A. Accordingly, there is a possibility that the gate electrode 34a comes down on the device.

As explained above, according to a mask of the present embodiment and the production method of a semiconductor device by using the same, combining accuracy of the complementarily divided patterns can be improved in one device element. Furthermore, according to the present embodiment, superimposing accuracy of patterns can be improved between device elements to be stacked, for example, between the active region 32 and the gate electrodes 34a to 34c in FIG. 9, between the gate electrodes 34a to 34c and other not shown wiring layer, and between the wiring layer of the gate electrodes 34a to 34c, etc. and the contact layer, etc. in addition to within one device element.

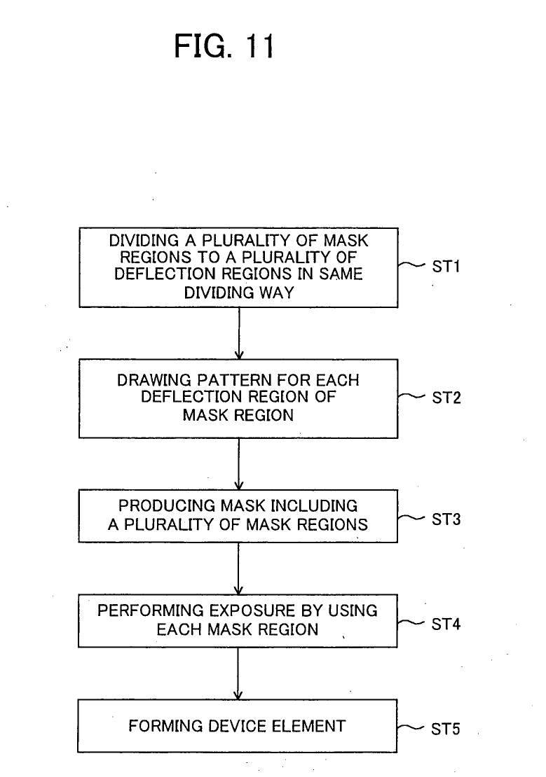

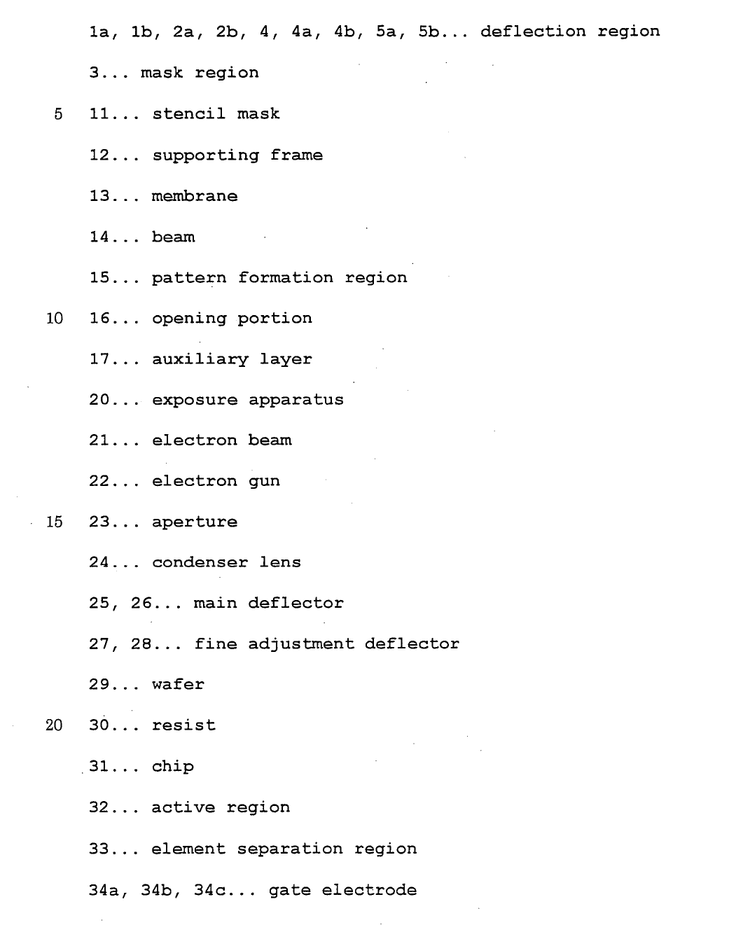

FIG. 11 shows a flow of producing a mask of the above embodiments 1 to 3 and producing a semiconductor device using the mask.

Step 1 (ST1)

A plurality of mask regions is divided to a plurality of deflection regions by a same dividing way.

Step 2 (ST2)

A pattern is drawn for each deflection region on the mask region. For example, an electron beam is used for the pattern drawing.

Step 3 (ST3)

A mask including a plurality of mask regions is produced. When forming a plurality of mask regions on mutually different masks, a plurality of masks are produced. When forming a plurality of masks on one mask, one mask is produced.

Step 4 (ST4)

Exposure is performed by using the respective mask regions. When patterns formed on the respective mask regions are patterns of different device elements, after exposing a pattern of one device, the device element is formed in a step 5. Then, a pattern of other device element is exposed (step 4) and the device element is formed (step 5).

When patterns formed on the respective mask regions are complementarily divided patterns of the same device element, the complementarily divided patterns formed on the plurality of mask regions are successively exposed, then, the exposed resist is developed. By using the resist pattern formed thereby as a mask, a device element is formed in the step 5.

Step 5 (ST5)

A device element is formed. As an example of forming a device element, processing of a gate layer or a contact, etc. by a base etching by using the resist pattern as a mask may be mentioned. A method of forming device elements is not limited to etching as above and may be, for example, ion implantation using a resist pattern as a mask.

Since a semiconductor device of embodiments of the present invention is formed with a pattern by following the above flow, aligning accuracy of patterns in a device element and between device elements is high. Accordingly, the pattern can be made finer and a semiconductor device can be made more highly integrated. Also, since aligning accuracy of patterns is improved, a yield of the semiconductor device is also improved.

According to a mask and a production method of a semiconductor device of embodiments of the present. invention as above, displacement of a plurality of mask patterns transferred to the same device can be matched. Accordingly, superimposing accuracy of respective device elements can be made high and combining accuracy of complementarily divided patterns can be made high. Accordingly, a yield of the semiconductor device is improved.

Embodiments of a mask, a production method of a semiconductor device and a semiconductor device of the present invention are not limited to the above explanations. For example, the complementary mask is not only a stencil mask formed with a complementarily divided pattern and may be a complementary mask of a phase shift mask used for photolithography. Also, the present invention can be applied to the case of dividing a pattern of a device element to three or more complementarily divided patterns and using three or more complementary masks. Other than the above, a variety of modifications can be made within the scope of the present invention.

According to a mask of the present invention, superimposing accuracy of mask patterns drawn on different regions on a plurality of masks or one mask can be made high.

According to a production method of a semiconductor device of the present invention, aligning accuracy of patterns in a device can be made high and a yield of the semiconductor device can be improved.

According to a semiconductor device of the present invention, a pattern can be made finer and a semiconductor device can be made more highly integrated.

1. A mask, including a plurality of lithography mask regions formed with mutually different mask patterns to be transferred to the same device, wherein:
said mask patterns of all of said mask regions are drawn by the same charged particle beam exposure means;
said mask pattern of each of said mask regions is drawn with being divided to a plurality of deflection regions;
said deflection region is in a range wherein a part of said mask pattern can be drawn on said mask region by deflecting a charged particle beam irradiated on said mask region without changing relative positions of said charged particle beam exposure means and said mask region; and
said deflection region is divided, so that said mask pattern in any deflection region of each of said mask regions is transferred on the same region on the device as said mask pattern in each one of deflection region of other mask region.

2. A mask as set forth in claim 1, wherein said charged particle beam is an electron beam.

3. A mask as set forth in claim 1, wherein a distribution of positional disposition of said mask patterns in said deflection regions approximately matches with distributions of positional disposition of said mask patterns in other deflection regions in said mask region and deflection regions of other mask region.

4. A mask as set forth in claim 1, wherein said mask patterns of said respective mask regions are patterns of different device elements.

5. A mask as set forth in claim 1, wherein said mask patterns of said respective mask regions are complementarily divided patterns for forming the same device element.

6. A mask as set forth in claim 1, wherein said mask is a stencil mask.

7. A mask as set forth in claim 1, wherein a plurality of said mask regions are formed on the same mask.

8. A production method of a semiconductor device, including a plurality of lithography steps for transferring to a device mask patterns of a mask having a plurality of mask regions on which said mutually different mask patterns are drawn by the same charged particle beam exposure means, wherein:
said mask pattern of said mask regions is drawn with being divided to a plurality of deflection regions;
said deflection region is in a range wherein a part of said mask pattern can be drawn on said mask region by deflecting a charged particle beam irradiated on said mask region without changing relative positions of said charged particle beam exposure means and said mask region; and
said deflection region is divided, so that said mask pattern in any deflection region of said mask regions is transferred on the same region on the device as said mask pattern in each one of deflection region of other mask region.

9. A production method of a semiconductor device as set forth in claim 8, wherein said charged particle beam is an electron beam.

10. A production method of a semiconductor device as set forth in claim 8, wherein said plurality of lithography steps are steps for transferring patterns of different device elements.

11. A production method of a semiconductor device as set forth in claim 8, wherein said plurality of lithography steps are steps for transferring complementarily divided patterns of the same device element.

12. A production method of a semiconductor device as set forth in claim 8, wherein said mask is a stencil mask.

13. A production method of a semiconductor device as set forth in claim 8, wherein a plurality of said mask regions is formed on the same mask.

14. A production method of a semiconductor device as set forth in claim 8, wherein said lithography step is proximity projection electron beam lithography.

15. A semiconductor device, on which mask patterns formed on a mask are transferred by a plurality of lithography steps, wherein:
said mask has a plurality of mask regions on which mutually different mask patterns are drawn by the same charged particle beam exposure means;
said mask pattern of each of said mask regions is drawn with being divided to a plurality of deflection regions;
said deflection region is in a range wherein a part of said mask pattern can be drawn on said mask region by deflecting a charged particle beam irradiated on said mask region without changing relative positions of said charged particle beam exposure means and said mask region; and
said deflection region is divided, so that said mask pattern in any deflection region of said mask regions is transferred on the same region on the device as said mask pattern in each one of deflection region of other mask region.

16. A semiconductor device as set forth in claim 15, wherein said charged particle beam is an electron beam.

17. A semiconductor device as set forth in claim 15, wherein said plurality of lithography steps are steps for transferring patterns of different device elements.

18. A semiconductor device as set forth in claim 15, wherein said plurality of lithography steps are steps for transferring complementarily divided patterns of the same device element.

19. A semiconductor device as set forth in claim 15, wherein said mask is a stencil mask.

20. A semiconductor device as set forth in claim 15, wherein a plurality of said mask regions are formed on the same mask.
